(19) United States
(12) Patent Application Publication
(10) Pub. No.: US 2024/0188234 A1
(43) Pub. Date: Jun. 6, 2024

(54) VEHICLE ELECTRONIC DEVICE AND STORAGE METHOD THEREOF

(71) Applicants: Innolux Corporation, Miaoli County (TW); CARUX TECHNOLOGY PTE. LTD., SINGAPORE (SG)

(72) Inventors: Kun-Feng Huang, Tainan (TW); Ta-Chin Huang, Tainan (TW); Ching-I Lo, Tainan (TW); Sheng-Yu Chiou, Miaoli County (TW)

(73) Assignees: Innolux Corporation, Miaoli County (TW); CARUX TECHNOLOGY PTE. LTD., SINGAPORE (SG)

(21) Appl. No.: 18/500,128

(22) Filed: Nov. 2, 2023

Related U.S. Application Data
(60) Provisional application No. 63/429,521, filed on Dec. 1, 2022.

(30) Foreign Application Priority Data
Aug. 24, 2023 (CN) 202311072733.1

(51) Int. Cl. H05K 5/02; B60K 35/00

(52) U.S. Cl. CPC H05K 5/02; B60K 35/00; B60K 2370/67

(57) ABSTRACT

A vehicle electronic device and a storage method therefore are provided. The vehicle electronic device includes a display unit, a motor driving assembly and a workbench. The motor driving assembly is connected to the display unit. An accommodating space with an opening is formed inside the workbench. The motor driving assembly moves and flips the display unit, so that the display unit is displayed on a surface of the workbench or accommodated in the accommodating space.

### CROSS-REFERENCE TO RELATED APPLICATION

This application claims the priority benefit of U.S. provisional application Ser. No. 63/429,521, filed on Dec. 1, 2022 and China application serial no. 202311072733.1, filed on Aug. 24, 2023. The entirety of each of the above-mentioned patent applications are hereby incorporated by reference herein and made a part of this specification.

### BACKGROUND

### Technical Field

The disclosure relates to an electronic device and a storage method thereof, and in particular relates to a vehicle electronic device and a storage method thereof.

### Description of Related Art

Currently, vehicle displays are fixed outside the dashboard, which occupy more space in the vehicle, and the usage is limited and inconvenient.

### SUMMARY

A vehicle electronic device and a storage method thereof, which may change the position of the display unit, offer greater operational freedom, and enhance flexibility in use, are provided in the disclosure.

According to an embodiment of the disclosure, a vehicle electronic device includes a display unit, a motor driving assembly, and a workbench. The motor driving assembly is connected to the display unit. An accommodating space with an opening is formed inside the workbench. The motor driving assembly moves and flips the display unit, so that the display unit is displayed on a surface of the workbench or accommodated in the accommodating space.

According to an embodiment of the disclosure, a storage method for a vehicle electronic device includes the following operation. A display unit and a motor driving assembly connected to the display unit are provided. A workbench is provided, and an accommodating space with an opening is formed inside the workbench. The motor driving assembly is driven, so that the display unit is displayed on a surface of the workbench or accommodated in the accommodating space. A normal direction of the display unit in a displayed state is different from a normal direction in a stored state.

Based on the above, in the embodiments of the disclosure, the motor driving assembly may move and flip the display unit so that the display unit is displayed on the surface of the workbench or accommodated in the accommodating space of the workbench, thereby changing the position of the display unit. Therefore, the display unit has greater operational freedom, and the vehicle electronic device of the disclosure has better flexibility in use.

### BRIEF DESCRIPTION OF THE DRAWINGS

FIG. 1A is a three-dimensional schematic diagram of a vehicle electronic device of an embodiment of the disclosure.

FIG. 1B is a three-dimensional schematic diagram of another viewing angle of FIG. 1A.

FIG. 1C is a three-dimensional schematic diagram of the display unit and the motor driving assembly in FIG. 1B.

FIG. 2A to FIG. 2D are front schematic diagrams and corresponding side schematic diagrams of a storage method of a vehicle electronic device of an embodiment of the disclosure.

FIG. 3A to FIG. 3H are front schematic diagrams and corresponding side schematic diagrams of a storage method of a vehicle electronic device of another embodiment of the disclosure.

FIG. 4A to FIG. 4C are front schematic diagrams of a storage method of a vehicle electronic device of another embodiment of the disclosure.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended claims to refer to specific elements. It should be understood by those skilled in the art that electronic apparatus manufacturers may refer to the same elements by different names. The disclosure does not intend to distinguish between elements that have the same function but have different names.

In the following description and claims, words such as “comprising” and “including” are open-ended words, so they should be interpreted as meaning “including but not limited to . . . ”.

In addition, relative terms, such as “below” or “bottom” and “above” or “top”, may be used in the embodiments to describe the relative relationship of one element of the drawing to another element. It is understood that if the device in the drawing is turned upside down, elements described as being on the “lower” side would then be elements described as being on the “upper” side.

In some embodiments of the disclosure, terms related to joining and connecting, such as “connected”, “interconnected”, etc., unless otherwise defined, may mean that two structures are in direct contact, or may also mean that two structures are not in direct (indirect) contact, in which there are other structures located between these two structures. The terms related to joining and connecting may also include the case where both structures are movable, or both structures are fixed. In addition, the term “coupling” includes the transfer of energy between two structures through direct or indirect electrical connection, or the transfer of energy between two separate structures through mutual induction.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

In the disclosure, the length, width, thickness, height, or area, or the distance or spacing between components may be measured by using an optical microscope (OM), a scanning electron microscope (SEM), a film thickness profilometer (α-step), an ellipsometer, or other suitable methods. In detail, according to some embodiments, a scanning electron microscope may be used to obtain a cross-sectional structure image including the component to be measured, and measure the length, width, thickness, height, or area of each component, or the distance or spacing between components, but not limited thereto.

Furthermore, the terms “a given range is from a first value to a second value”, “a given range is within a range from the first value to the second value” means that the given range includes the first value, the second value, and other values in between. If a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees. The terms “about”, “equal to”, “equal” or “same”, “substantially” or “generally” are interpreted as within 20% of a given value or range, or interpreted as within 10%, 5%, 3%, 2%, 1%, or 0.5% of the given value or range.

Although the terms “first”, “second”, “third”, . . . may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

Unless otherwise defined, all terms (including technical and scientific terms) used herein have the same meaning as commonly understood by one of ordinary skill in the art to which this disclosure belongs. It is understood that these terms, such as those defined in commonly used dictionaries, should be interpreted as having meanings consistent with the relevant art and the background or context of the disclosure, and should not be interpreted in an idealized or overly formal manner, unless otherwise defined herein.

It should be noted that, in the following embodiments, the technical features in several different embodiments may be replaced, reorganized, and mixed to complete other embodiments without departing from the spirit of the disclosure.

References of the exemplary embodiments of the disclosure are to be made in detail. Examples of the exemplary embodiments are illustrated in the drawings. If applicable, the same reference numerals in the drawings and the descriptions indicate the same or similar parts.

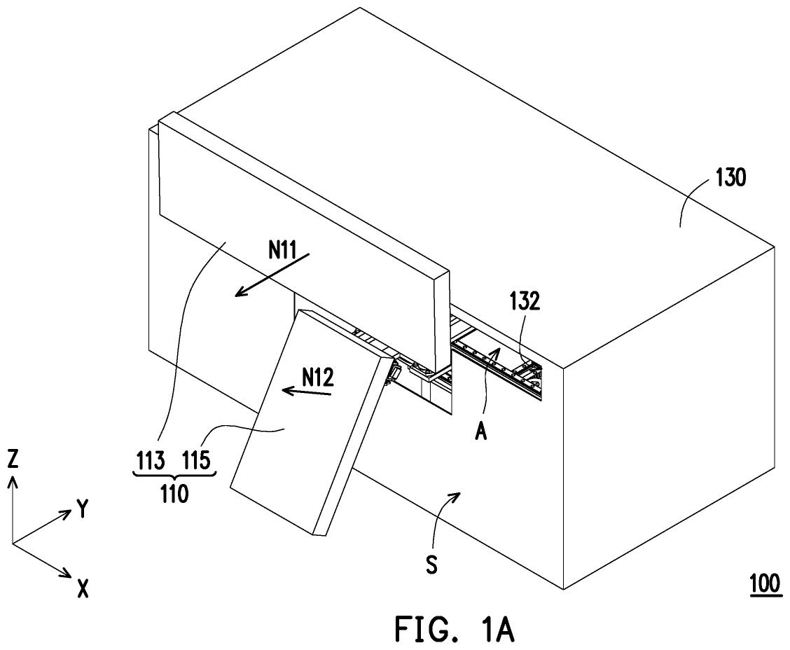

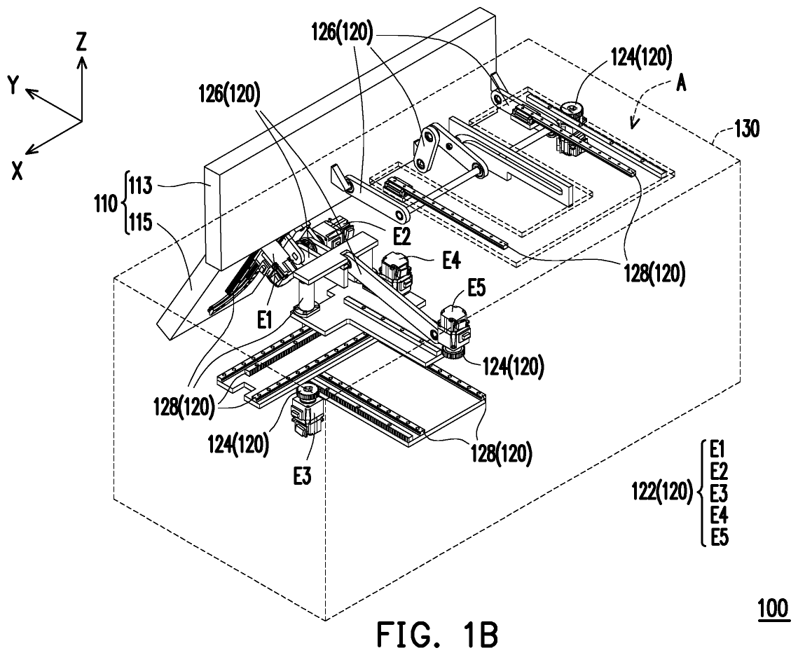

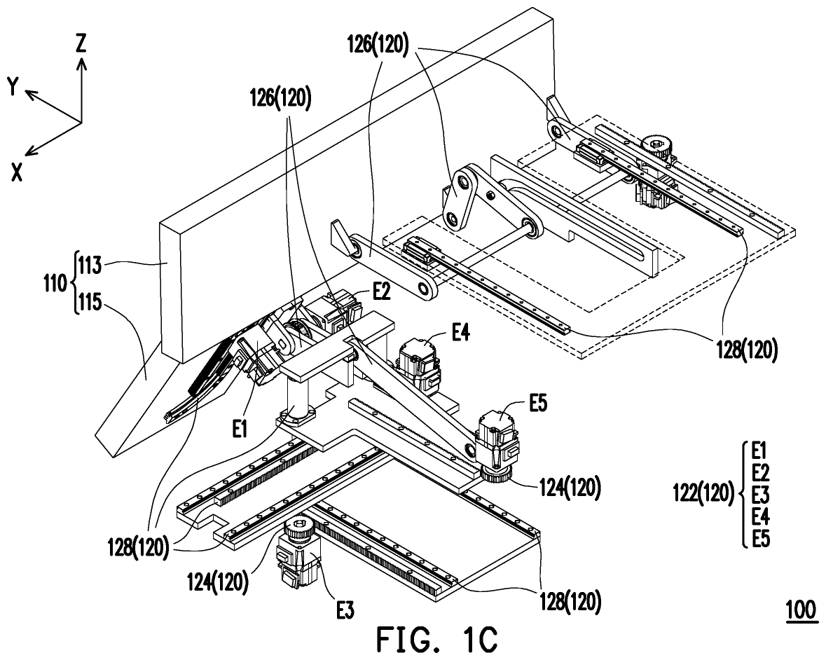

FIG. 1A is a three-dimensional schematic diagram of a vehicle electronic device of an embodiment of the disclosure. FIG. 1B is a three-dimensional schematic diagram of another viewing angle of FIG. 1A. FIG. 1C is a three-dimensional schematic diagram of the display unit and the motor driving assembly in FIG. 1B. For clarity of description, the center control platform in FIG. 1B is represented by a dashed line.

Referring to FIG. 1A, FIG. 1B, and FIG. 1C simultaneously, in this embodiment, the vehicle electronic device 100 includes a display unit 110, a motor driving assembly 120, and a workbench 130. The motor driving assembly 120 is connected to the display unit 110. An accommodating space A with an opening 132 is formed inside the workbench 130. The motor driving assembly 120 moves and flips the display unit 110, so that the display unit 110 is displayed on a surface S of the workbench 130 or accommodated in the accommodating space A. The workbench 130 may be, for example, the front of the cab or the center control platform in front of the driver and passenger. The workbench 130 may be, for example, a carrier installed with one or a combination of devices such as a dashboard panel, air conditioner, audio panel, storage box, air bag, etc., but not limited thereto. The accommodating space A may be a closed space in normal conditions, and may be an open space when the vehicle electronic device 100 switches states. The accommodating space A may also be an open space both in the normal state and during state switching, but not limited thereto.

Specifically, in this embodiment, the vehicle electronic device 100 is adapted for installation in a vehicle. The vehicle electronic device 100 may be disposed in front of the driver seat and/or the passenger seat, such as in the dashboard of the workbench 130 for the driver and/or the passenger to view. In one embodiment, the vehicle electronic device 100 may also be a display disposed on the roof of the vehicle, a display disposed behind the seat, or a display disposed next to the door, etc., which is not limited thereto.

The display unit 110 of this embodiment may include a first display unit 113 and a second display unit 115. In an embodiment, the area of the first display unit 113 may be greater than the area of the second display unit 115. The first display unit 113 and the second display unit 115 may be, for example, non-self-luminous displays, such as liquid crystal displays (LCD), or self-luminous displays, such as organic light-emitting diodes (OLED) displays, micro light-emitting diode (micro-LED) displays, mini light-emitting diode (mini-LED) displays, or quantum dot LED displays, but not limited thereto.

In one embodiment, the motor driving assembly 120 may include one or a combination of a driving member 122, a transmission member 124, and a linkage member 126. For example, the driving member 122 may be driven to drive the transmission member 124 and the linkage member 126, such that the display unit 110 is driven to move and flip. Alternatively, in an embodiment, the motor driving assembly 120 may include one or a combination of a driving member 122, a transmission member 124, a linkage member 126, and a guide unit 128. For example, the driving member 122 may be driven so that the transmission member 124 moves along the guide unit 128 to link the movement of the linkage member 126, such that the display unit 110 is driven to move and flip. In one embodiment, the motor driving assembly 120 may include a motor E1 that is configured to rotate the display unit 110. In one embodiment, the motor driving assembly 120 may include a motor E2 that is configured to change the tilt angle of the display unit 110. In one embodiment, the motor driving assembly 120 may include a motor E3 that is configured to change the position of the display unit 110 in the Y direction. In one embodiment, the motor driving assembly 120 may include a motor E4 that is configured to change the position of the display unit 110 in the X direction. In one embodiment, the motor driving assembly 120 may include a motor E5 that is configured to change the position of the display unit 110 in the Z direction. As shown in FIG. 1B and FIG. 1C, the driving member 122 of the motor driving assembly 120 in this embodiment may include a motor E1, a motor E2, a motor E3, a motor E4, and a motor E5. The display unit 110 is driven to move and flip by driving the motor E1, the motor E2, the motor E3, the motor E4, and the motor E5. Here, the movement may be, for example, a change in the position of the object in any direction of X, Y, and Z. The flipping may be, for example, an object turning along an axis. Specifically, it may be, for example, turning along the X-axis direction. The rotation may be, for example, an object turning along an axis. Specifically, it may be, for example, turning along the Y-axis direction. The tilt angle may be, for example, the included angle between the normal direction of the display unit and the Y-axis direction. The driving member 122 may be, for example, a device that converts electrical energy into mechanical energy, and may include one or a combination of a DC motor, an AC motor, a synchronous motor, and an asynchronous motor. The transmission member 124 and the linkage member 126 may, for example, serve as a device for transmitting power and changing the direction of power. Their materials may include one or a combination of metal, organic/inorganic compounds, plastics, fibers, ceramics, etc., but are not limited thereto. The transmission member 124 may be, for example, a gear, a pulley assembly, a lever, an axle, a pulley, an inclined plane, a wedge, or a helical structure, and the linkage member 126 may be, for example, a connecting rod, a pulley assembly, a lever, an axle, a pulley, an inclined plane, a wedge, or a helical structure. The guide unit 128 may guide the object to move along a movement trajectory, and the movement trajectory may be, for example, one or a combination of a linear trajectory, a reciprocating trajectory, an arc trajectory, but not limited thereto. The guide unit 128 may be, for example, a slide rail, a rail, a rack, a groove, or a sleeve, but not limited thereto.

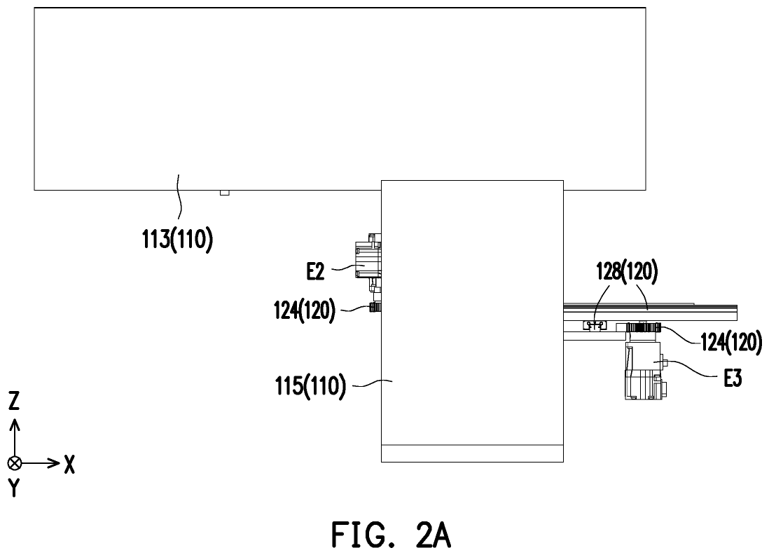

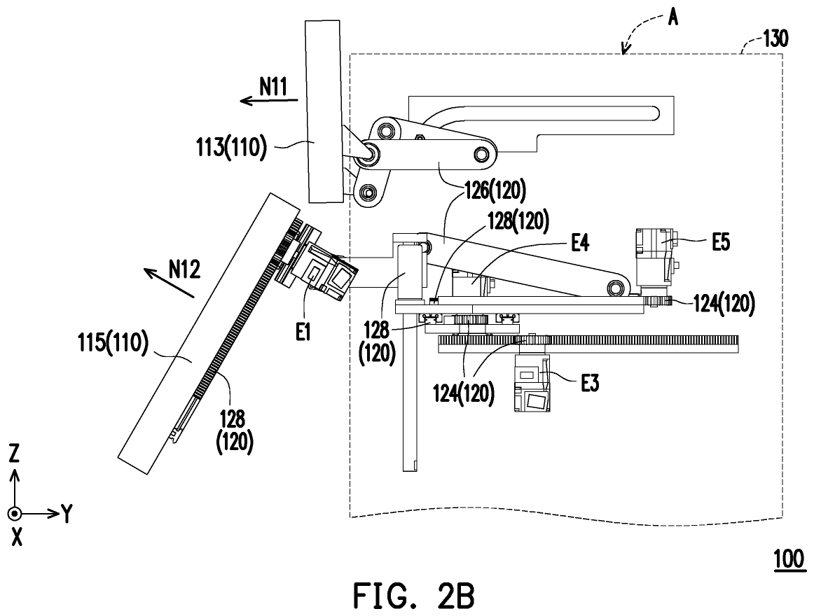

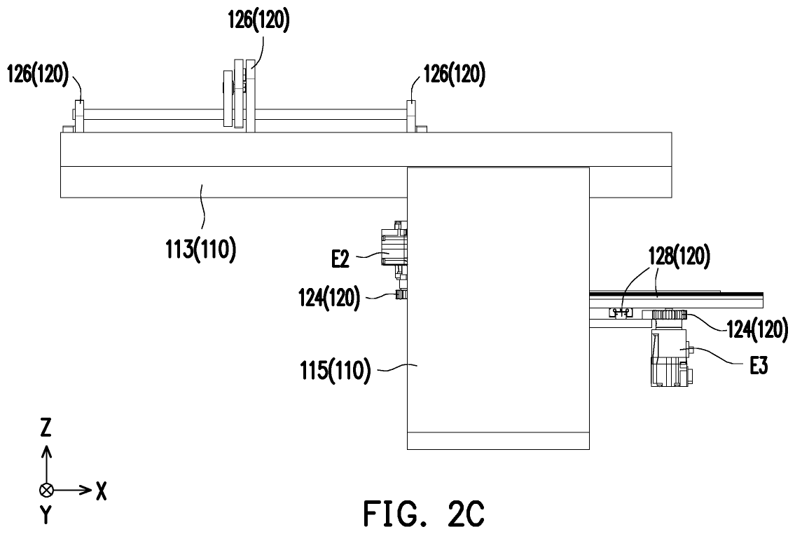

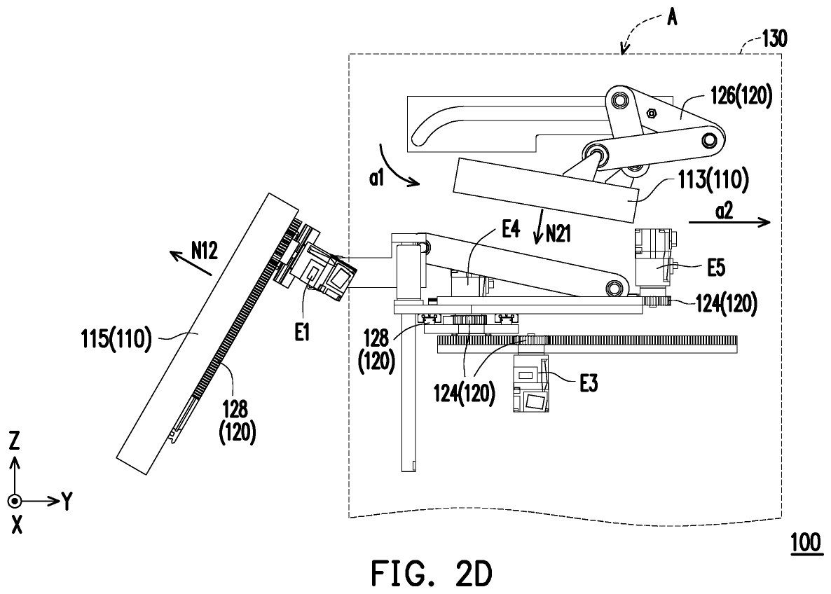

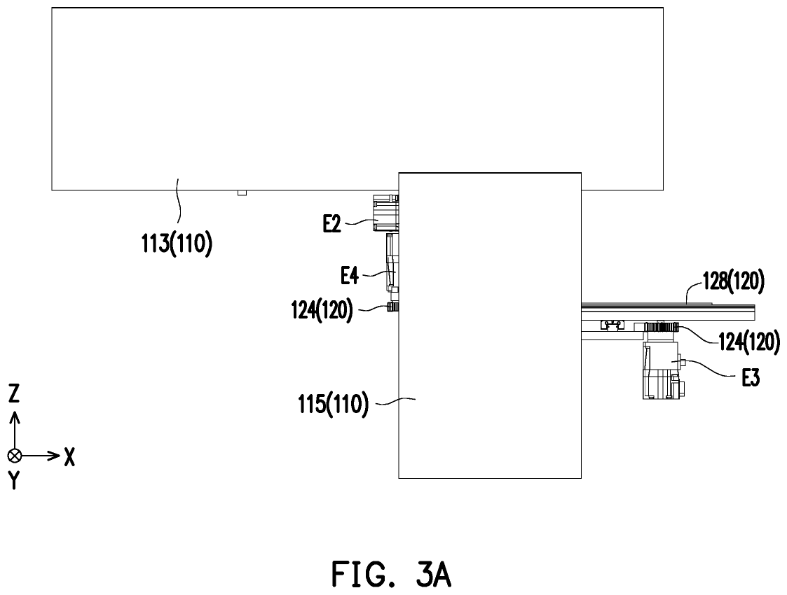

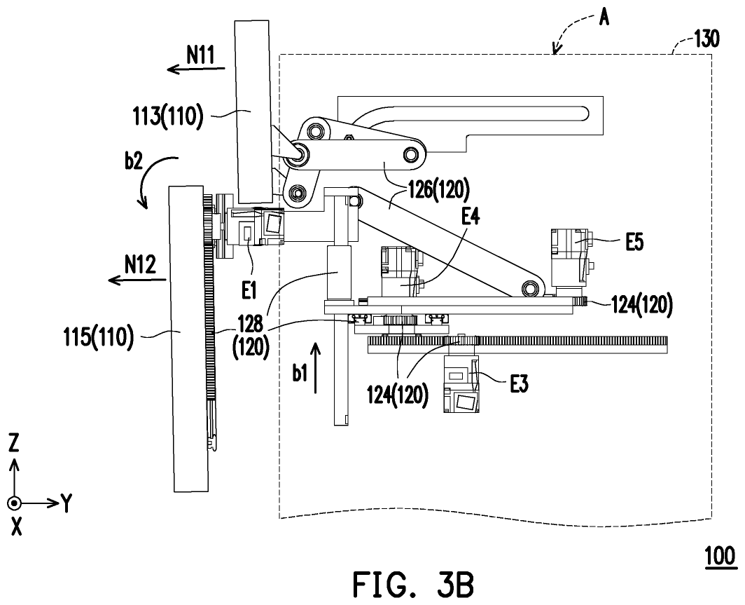

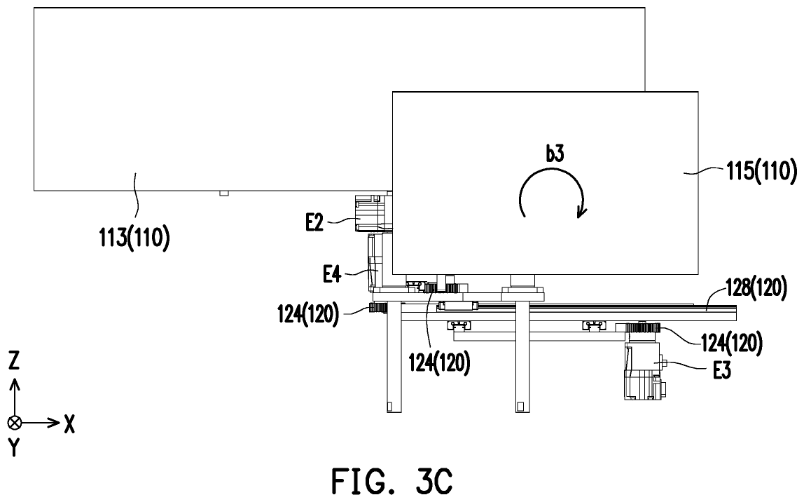

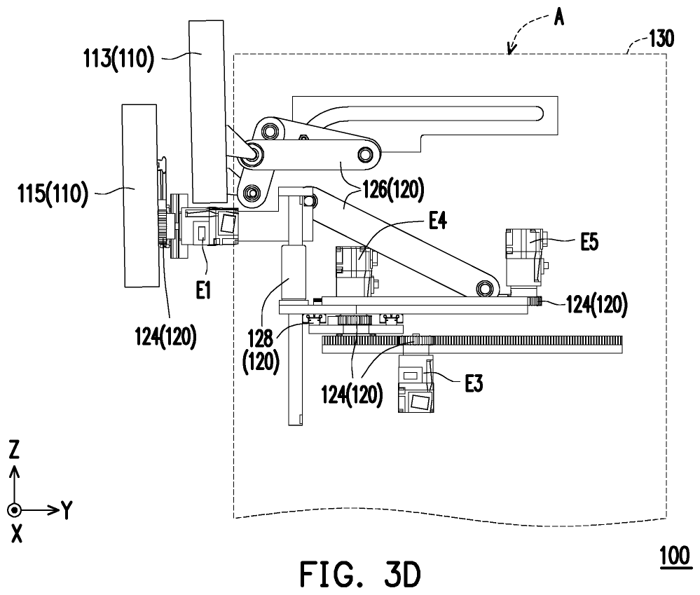

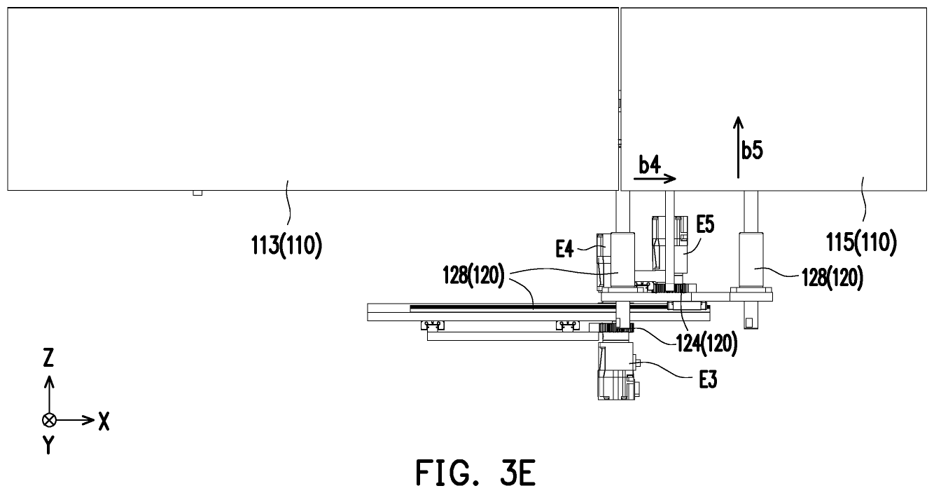

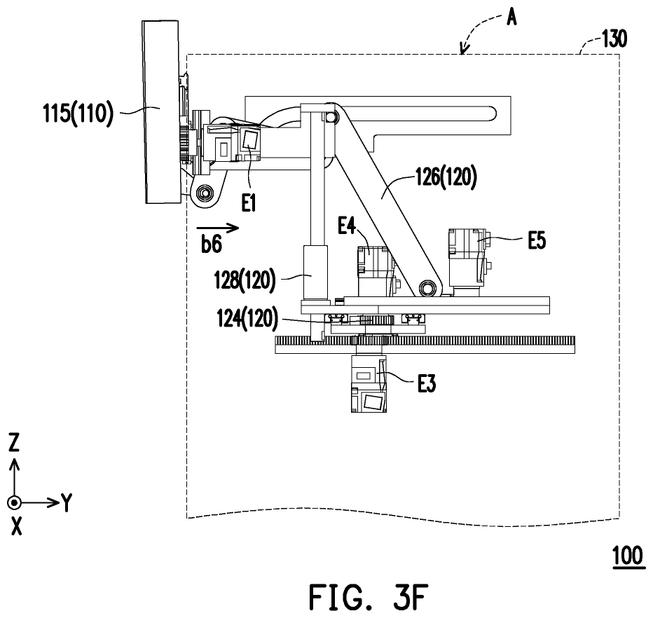

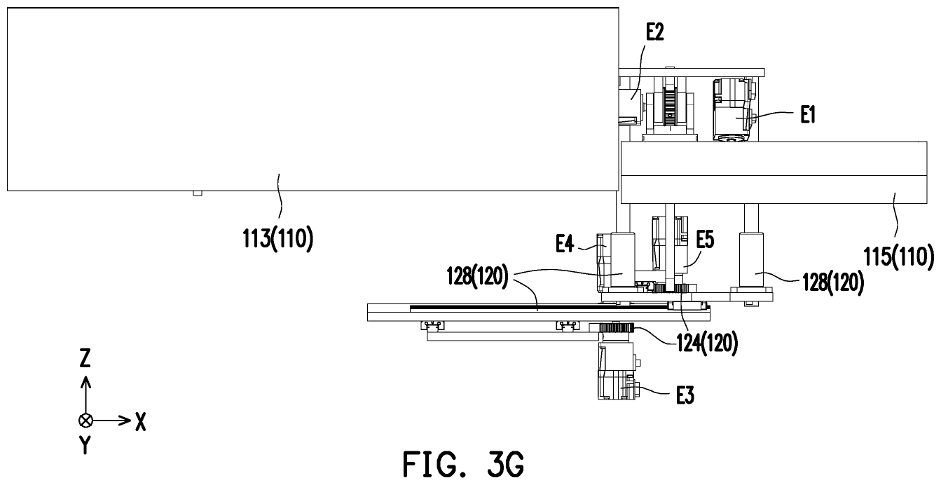

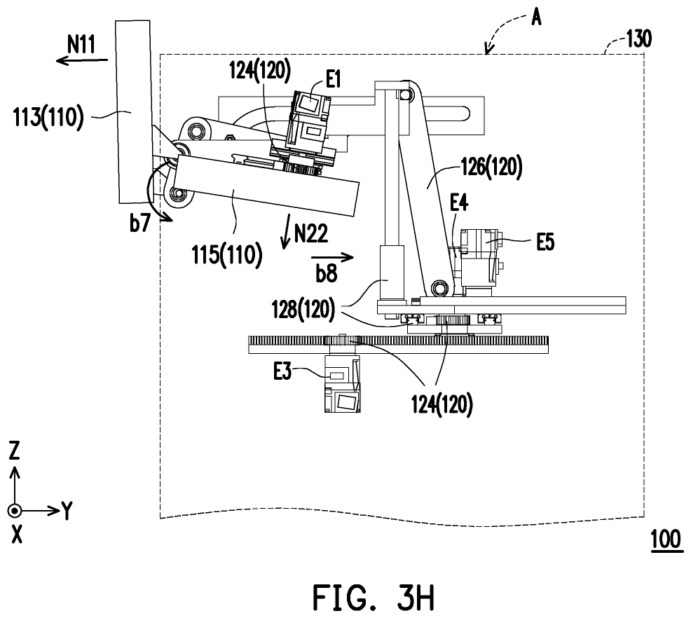

The storage method of the vehicle electronic device of this embodiment includes the following steps. Referring to FIG. 1A and FIG. 1B simultaneously, firstly, a display unit 110 and a motor driving assembly 120 connected to the display unit 110 are provided. Next, a workbench 130 is provided, in which an accommodating space A with an opening 132 is formed inside the workbench 130. Afterwards, the motor driving assembly 120 is driven, so that the display unit 110 is displayed on a surface S of the workbench 130 or accommodated in the accommodating space A. The normal directions N11 and N12 of the first display unit 113 and the second display unit 115 of the display unit 110 in the displayed state (referring to FIG. 2B) are different from the normal directions N21 and N22 in the stored state (referring to FIG. 2D and FIG. 3H).

FIG. 2A to FIG. 2D are front schematic diagrams and corresponding side schematic diagrams of a storage method of a vehicle electronic device of an embodiment of the disclosure. It should be noted that FIG. 2A and FIG. 2C are front schematic diagrams, and FIG. 2B and FIG. 2D are side schematic diagrams respectively corresponding to FIG. 2A and FIG. 2C. For the sake of clarity, the workbench 130 is omitted in FIG. 2A and FIG. 2C, while the workbench 130 is represented by dashed lines in FIG. 2B and FIG. 2D.

In detail, referring to FIG. 2A and FIG. 2B first, the first display unit 113 and the second display unit 115 of the display unit 110 are in a displayed state, in which the normal direction N11 of the first display unit 113 is not parallel to the normal direction N12 of the second display unit 115. Next, referring to FIG. 2A, FIG. 2B, FIG. 2C, and FIG. 2D simultaneously, the motor driving assembly 120 is driven, so that the first display unit 113 may be flipped downward along the arrow direction a1 to approximately horizontal. Afterwards, the first display unit 113 may be moved backward along the arrow direction a2 to retract into the accommodating space A of the workbench 130, to be in a stored state. At this time, the normal direction N11 of the first display unit 113 in the displayed state (referring to FIG. 2B) is different from the normal direction N21 in the stored state (referring to FIG. 2D). Since the first display unit 113 of the display unit 110 is accommodated in the accommodating space A through the motor driving assembly 120, a sense of greater space may be created inside the vehicle. The term ‘horizontal’ may refer to a state that is substantially parallel to a reference plane, in which reference plane may be, for example, the ground, the bottom of a vehicle, the top of a vehicle, the top of a workbench 130, or the surface of a bottom portion. Specifically, if the difference between the normal direction of the reference plane and the normal direction of the object is within 10 degrees, it may be considered a “horizontal” embodiment.

FIG. 3A to FIG. 3H are front schematic diagrams and corresponding side schematic diagrams of a storage method of a vehicle electronic device of another embodiment of the disclosure. It should be noted that FIG. 3A, FIG. 3C, FIG. 3E, and FIG. 3G are front schematic diagrams, and FIG. 3B, FIG. 3D, FIG. 3F, and FIG. 3H are side schematic diagrams respectively corresponding to FIG. 3A, FIG. 3C, FIG. 3E, and FIG. 3G. For the sake of clarity, the workbench 130 is omitted in FIG. 3A, FIG. 3C, FIG. 3E, and FIG. 3G, while the workbench 130 is represented by dashed lines in FIG. 3B, FIG. 3D, FIG. 3F, and FIG. 3H.

In detail, referring to FIG. 3A and FIG. 3B first, the first display unit 113 and the second display unit 115 of the display unit 110 are in a displayed state, in which the normal direction N11 of the first display unit 113 is not parallel to the normal direction N12 of the second display unit 115. Next, referring to FIG. 3A, FIG. 3B, FIG. 3C, and FIG. 3D simultaneously, the motor driving assembly 120 is driven, so that the second display unit 115 may first move upward along the arrow direction b1. Next, the second display unit 115 may be rotated downward along the arrow direction b2 to be parallel to the first display unit 113. Next, the second display unit 115 may be rotated 90 degrees along the arrow direction b3. Next, referring to FIG. 3C, FIG. 3D, FIG. 3E, and FIG. 3F simultaneously, the second display unit 115 may be moved to the right along the arrow direction b4, and the second display unit 115 may be moved upward along the arrow direction b5 to be aligned with the first display unit 113. Then, the second display unit 115 may be moved backward along the arrow direction b6 to be aligned with the first display unit 113. Afterwards, referring to FIG. 3E, FIG. 3F, FIG. 3G, and FIG. 3H simultaneously, the second display unit 115 may be flipped down along the arrow direction b7 to approximately horizontal, and the second display unit 115 may be moved backward along the arrow direction b8 to retract into the accommodating space A of the workbench 130. At this time, the normal direction N12 of the second display unit 115 in the displayed state (referring to FIG. 3B) is different from the normal direction N22 in the stored state (referring to FIG. 3H). Since the second display unit 115 of the display unit 110 is accommodated in the accommodating space A through the motor driving assembly 120, a sense of greater space may be created inside the vehicle.

In an embodiment not shown, the motor driving assembly is driven, so that the first display unit and the second display unit may be flipped downward simultaneously, and then the first display unit and the second display unit may also be moved backward simultaneously to retract into the accommodating space of the workbench. That is, both the first display unit and the second display unit of the display unit may be horizontally accommodated in the accommodating space, so that a sense of greater space is created inside the vehicle.

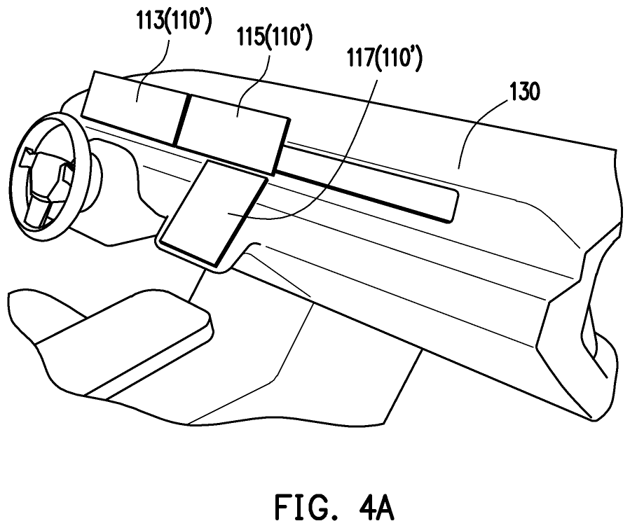

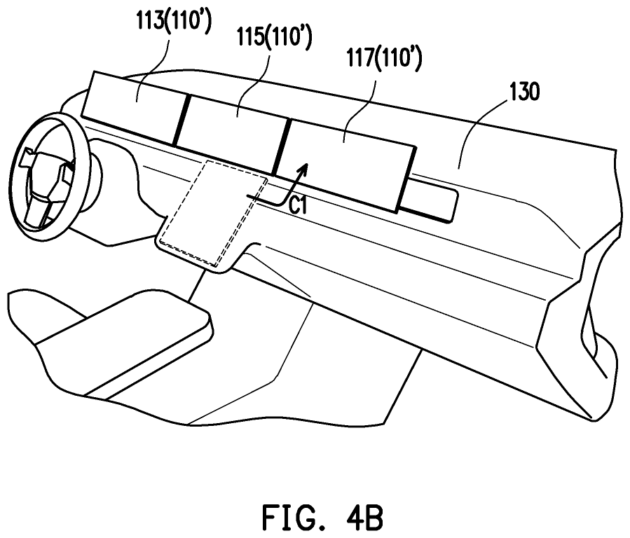

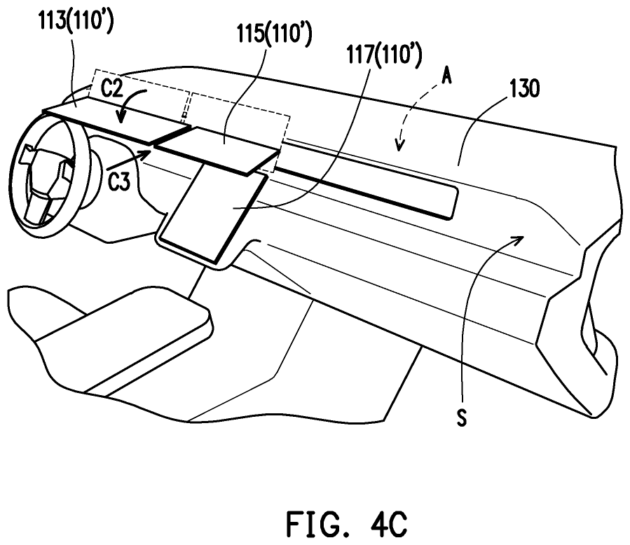

FIG. 4A to FIG. 4C are front schematic diagrams of a storage method of a vehicle electronic device of another embodiment of the disclosure. Specifically, referring to FIG. 4A, the first display unit 113 and the second display unit 115 of the display unit 110′ are arranged side by side, and the third display unit 117 is located below the second display unit 115, forming the first displayed state. Next, referring to FIG. 4A and FIG. 4B simultaneously, the third display unit 117 may be rotated to the right side of the second display unit 115 along the arrow direction c1 to form a second displayed state. Finally, the first display unit 113 and the second display unit 115 may be rotated downward along the arrow direction c2 to be horizontal, and the first display unit 113 and the second display unit 115 may be moved backward along the arrow direction c3 to retract into the accommodating space A of the workbench 130 to form a third displayed state in which only the third display unit 117 is on the surface S of the workbench 130.

To sum up, in the embodiments of the disclosure, the motor driving assembly may move and flip the display unit so that the display unit is displayed on the surface of the workbench or accommodated in the accommodating space of the workbench, thereby changing the position of the display unit. Therefore, the display unit has greater operational freedom, and the vehicle electronic device of the disclosure has better flexibility in use.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure.

What is claimed is:

1. A vehicle electronic device, comprising:
a display unit;
a motor driving assembly, connected to the display unit; and
a workbench, wherein an accommodating space with an opening is formed inside the workbench, wherein the motor driving assembly moves and flips the display unit, so that the display unit is displayed on a surface of the workbench or accommodated in the accommodating space.

2. The vehicle electronic device according to claim 1, wherein the display unit is horizontally accommodated in the accommodating space.

3. The vehicle electronic device according to claim 1, wherein the motor driving assembly comprises a driving member, a transmission member, and a linkage member.

4. The vehicle electronic device according to claim 3, wherein the driving member is driven to drive the transmission member and the linkage member, such that the display unit is driven to move and flip.

5. The vehicle electronic device according to claim 1, wherein the motor driving assembly comprises a driving member, a transmission member, a linkage member, and a guide unit.

6. The vehicle electronic device according to claim 5, wherein the driving member is driven so that the transmission member moves along the guide unit to link a movement of the linkage member, such that the display unit is driven to move and flip.

7. The vehicle electronic device according to claim 5, wherein the driving member comprises one or a combination of a DC motor, an AC motor, a synchronous motor, and an asynchronous motor.

8. The vehicle electronic device according to claim 5, wherein the transmission member comprises a gear, a pulley assembly, a lever, an axle, a pulley, an inclined plane, a wedge, or a helical structure.

9. The vehicle electronic device according to claim 5, wherein the linkage member comprises a connecting rod, a pulley assembly, a lever, an axle, a pulley, an inclined plane, a wedge, or a helical structure.

10. The vehicle electronic device according to claim 5, wherein the guide unit comprises a slide rail, a rail, a rack, a groove, or a sleeve.

11. The vehicle electronic device according to claim 1, wherein the motor driving assembly comprises a driving member that is configured to rotate the display unit.

12. The vehicle electronic device according to claim 1, wherein the motor driving assembly comprises a driving member that is configured to change a tilt angle of the display unit.

13. The vehicle electronic device according to claim 1, wherein the motor driving assembly comprises a driving member that is configured to change a position of the display unit in a Y direction.

14. The vehicle electronic device according to claim 1, wherein the motor driving assembly comprises a driving member that is configured to change a position of the display unit in an X direction.

15. The vehicle electronic device according to claim 1, wherein the motor driving assembly comprises a driving member that is configured to change a position of the display unit in a Z direction.

16. The vehicle electronic device according to claim 1, wherein the display unit comprises a first display unit and a second display unit, an area of the first display unit is greater than an area of the second display unit.

17. The vehicle electronic device according to claim 16, wherein the first display unit of the display unit is accommodated in the accommodating space through the motor driving assembly.

18. The vehicle electronic device according to claim 17, wherein the second display unit of the display unit is accommodated in the accommodating space through the motor driving assembly.

19. The vehicle electronic device according to claim 17, wherein the first display unit and the second display unit of the display unit are accommodated in the accommodating space through the motor driving assembly.

20. A storage method of a vehicle electronic device, comprising:
providing a display unit and a motor driving assembly connected to the display unit;
providing a workbench, and forming an accommodating space with an opening inside the workbench; and
driving the motor driving assembly, so that the display unit is displayed on a surface of the workbench or accommodated in the accommodating space, wherein a normal direction of the display unit in a displayed state is different from a normal direction in a stored state.
